(19) United States
(12) Patent Application Publication
(10) Pub. No.: US 2003/0003732 A1
(43) Pub. Date: Jan. 2, 2003

(54) Method of post treatment for a metal line of semiconductor device

(76) Inventor: Jae Suk Lee, Kyoungki-do (KR)

Correspondence Address: WILDMAN, HARROLD, ALLEN & DIXON, 225 WEST WACKER DRIVE, CHICAGO, IL, 60606, US

(21) Appl. No.: 10/180,735

(22) Filed: Jun. 26, 2002

(30) Foreign Application Priority Data
Jun. 27, 2001 (KR) 2001-36954

(51) Int. Cl. H01L 21/44; H01L 21/4763

(52) U.S. Cl. 438/688; 438/643

(57) ABSTRACT

Disclosed is a method of post treatment for a metal line of semiconductor device, wherein an aluminum oxide layer is employed as a protecting layer of metal line, thereby improving reliability thereof. The disclosed comprises the steps of: forming aluminum having a predetermined thickness on the entire surface of substrate having the metal line by performing a deposition process; performing a plasma treatment on a predetermined processing condition, thereby changing the aluminum into a lower barrier layer of aluminum oxide layer; and forming an inter metal dielectric layer on the entire surface of the lower barrier layer by performing a deposition process.

### BACKGROUND OF THE INVENTION

1. Field of the Invention

The present invention relates to a method of post treatment for a metal line of semiconductor device, and more particularly to a method of post treatment of semiconductor device for a metal line formed on a substrate in a predetermined pattern.

2. Description of the Prior Art

As is generally known, a patterning process is performed to form a metal line having a various shape in a semiconductor device. A dry etch process using plasma may be mentioned as an example of etch process for forming a metal line by etching aluminum alloy into a predetermined pattern.

The metal line on the substrate is filled up by Inter Metal Dielectric (IMD) in accordance with a post treatment process to compensate a time constant. A low-dielectric-constant fluorine doped silicon glass (FSG) is widely used as the metal dielectric.

In the FSG, the main component F is a corrosive gas, causing metal etching in contact with metal. Therefore, if the F is increased to lower dielectric constant, metal corrosion is generated, thereby degrading reliability of semiconductor device.

Therefore, as shown in FIGS. 1A to 1C, a TEOS oxide layer or HDP USG (High Density Plasma Undoped Silicon Glass) has been formed as a protecting layer (a lower layer of FSG) prior to the application of FSG.

FIGS. 1A to 1C are drawings showing a conventional method of post treatment for a metal line.

Referring to FIG. 1A, a metal line 104 is formed on a substrate 102 in a predetermined pattern. And, as shown in FIG. 1B, a protecting layer 106 is formed with a predetermined thickness prior to forming FSG as IMD to reduce time constant. A TEOS oxide layer or HDP USG is generally employed as the protecting layer 106.

Subsequently, as shown in FIG. 1C, a deposition process is performed to form a fluorine doped silicon glass (FSG) 108 on the entire surface of the protecting layer 106, thereby completing post treatment for the metal line 104 on the substrate 102. The time constant is compensated by the resulting FSG.

However, the protecting layer of TEOS oxide layer or HDP USG is subject to many drawbacks that the insulation is relatively low and that it is difficult to completely prevent the diffusion of F in FSG, thereby corroding the metal line and lowering reliability. Moreover, the stress between different materials (TEOS oxide layer or HDP USG and metal material) also results in the degradation of reliability of metal line.

### SUMMARY OF THE INVENTION

Therefore, the present invention has been proposed to solve the above problems and the primary objective of the present invention is to provide a method of post treatment for a metal line of semiconductor device capable of improving reliability of metal line by employing aluminum oxide layer as a protecting layer of metal line.

In order to accomplish the above objective, one aspect of the present invention comprises the steps of: forming aluminum having a predetermined thickness on the entire surface of substrate having the metal line by a deposition process; changing the aluminum into a lower barrier layer of aluminum oxide layer by performing plasma treatment under a predetermined processing condition; and forming an inter metal dielectric layer on the entire surface of the lower barrier layer by performing a deposition process.

Another aspect of the present invention comprises the steps of: forming a lower barrier layer of aluminum oxide layer having a predetermined thickness on the entire surface of substrate having the metal line by performing a deposition process; and performing a deposition process to form an inter metal dielectric layer on the entire surface of the lower barrier layer.

### BRIEF DESCRIPTION OF THE DRAWINGS

FIGS. 1A to 1C are drawings showing a conventional method of post treatment for a metal line.

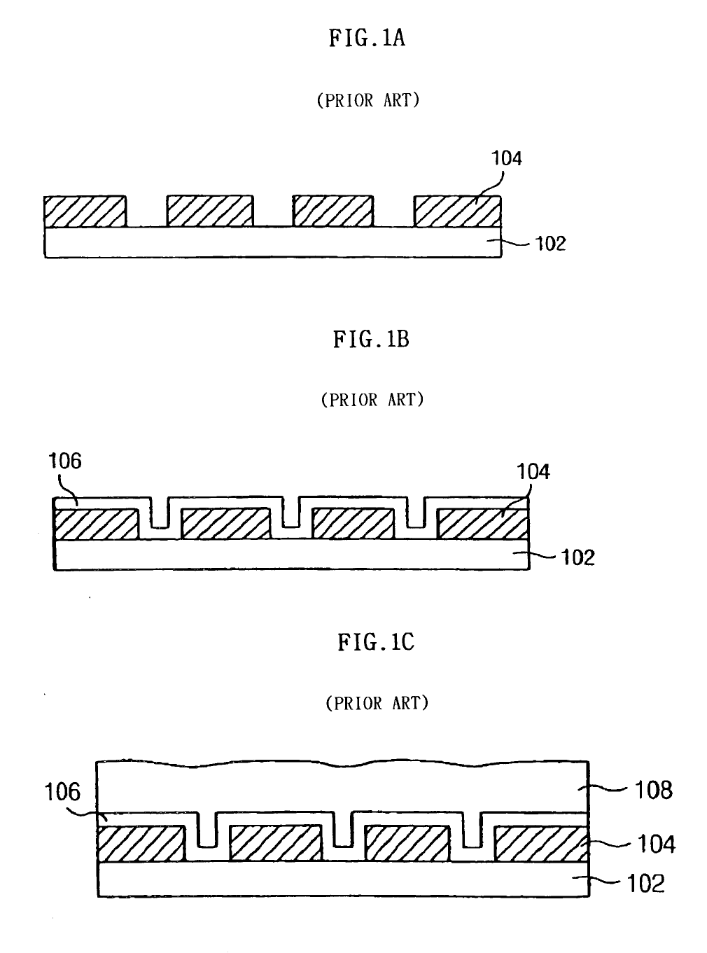

FIGS. 2A to 2C are drawings showing later processes on a wafer having a metal line for post treatment of a metal line according to the present invention.

### DETAILED DESCRIPTION OF THE INVENTION

The objects and features of the invention may be understood with reference to the following detailed description of an illustrative embodiment of the invention, taken together with the accompanying drawings.

The main point of the present invention is that aluminum oxide layer (Al₂O₃) is employed, differently from the conventional method using TEOS oxide layer or HDP USG as a protecting layer. The Al₂O₃ has improved insulation and prevents the diffusion of F and is similar material to the metal line, thereby realizing the objectives of the present invention.

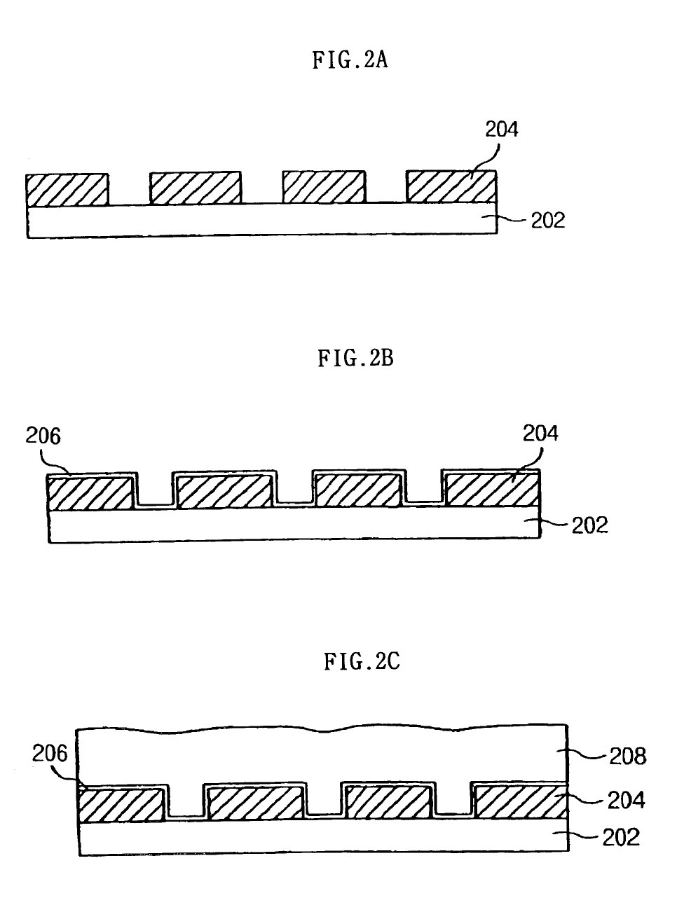

FIGS. 2A to 2C are drawings showing a later process on a wafer having a metal line for post treatment of a metal line according to the present invention.

Referring to FIG. 2A, a metal line 204 is formed in a predetermined pattern on a substrate 202. And, as shown in FIG. 2B, Al is deposited to have a predetermined thickness (for example 80˜150 Å, preferably 100 Å) as a lower barrier material on the entire surface of the metal line 204 in accordance with a CVD or PVD prior to the formation of FSG as IMD to reduce a time constant.

Subsequently, a plasma treatment is performed on the lower barrier material (Al) with O₂ or N₂O under a predetermined processing condition, thereby changing the lower barrier material (Al) into a lower barrier layer 206 of aluminum oxide layer Al₂O₃.

Compared with TEOS oxide layer or HDP USG, the Al₂O₃ on the metal line 204 has improved insulation and prevents diffusion of F in an inter metal dielectric layer 208 to be formed on the lower barrier layer 206 by a later process, not generating stress with the metal line 204.

Subsequently, as shown in FIG. 2C, a deposition process is performed to form a FSG 208 on the upper surface of the lower barrier layer 206, thereby a post treatment for the metal line formed on the substrate 202 is completed and RC delay is compensated by the FSG.

In the above embodiment, Al₂O₃ is formed as a lower barrier layer on the metal line by depositing Al and performing a plasma treatment. However, it is illustrated only as an embodiment, and the Al₂O₃ may be formed on the metal line in accordance with a CVD process to accomplish the objective.

As described above, according to the present invention, an aluminum oxide layer (Al₂O₃), similar material to the metal line, is employed as a lower barrier layer to protect metal line, thereby improving insulation and preventing diffusion of F. Moreover, it is also possible to reduce stress with metal line, thereby increasing reliability of metal line.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method of post treatment for a metal line of semiconductor device comprising the steps of:
forming aluminum having a predetermined thickness on the entire surface of substrate having the metal line by performing a deposition process;
performing a plasma treatment on a predetermined processing condition, thereby changing the aluminum into a lower barrier layer of aluminum oxide layer; and
forming an inter metal dielectric layer on the entire surface of the lower barrier layer by performing a deposition process.

2. The method of claim 1, wherein the aluminum has a thickness in the range of 80 to 150 Å.

3. The method of claim 1, wherein the plasma treatment is performed with O₂ or N₂O.

4. A method of post treatment for a metal line of semiconductor device comprising the steps of:
forming a lower barrier layer of aluminum oxide layer having a predetermined thickness on the entire surface of substrate having the metal line by performing a deposition process; and
forming an inter metal dielectric layer on the entire surface of the lower barrier layer by performing a deposition process.
